(19) United States
(12) Patent Application Publication
(10) Pub. No.: US 2011/0114153 A1
(43) Pub. Date: May 19, 2011

(54) PHOTOVOLTAIC SOLAR COLLECTION AND TRACKING SYSTEM

(75) Inventors: Charles Almy, Berkeley, CA (US); Stephen Barsun, Davis, CA (US); Reuben Sandler, Berkeley, CA (US); Brian Wares, Sacramento, CA (US); Elizabeth Wayman, Richmond, CA (US)

(73) Assignee: SUNPOWER CORPORATION, San Jose, CA (US)

(21) Appl. No.: 12/776,185

(22) Filed: May 7, 2010

Related U.S. Application Data
(60) Provisional application No. 61/176,669, filed on May 8, 2009.

(51) Int. Cl. H01L 31/052; H01L 31/18; B23P 11/00

(52) U.S. Cl. 136/246; 29/890.033; 29/428

(57) ABSTRACT

A photovoltaic sun tracking system including a photovoltaic assembly, a first mounting structure, and a second mounting structure. The photovoltaic assembly includes at least one PV cell maintained by framework defining a PV plane. The first and second mounting structures are mounted to a support surface and rotatably maintain the framework at first and second pivot points, respectively, to establish a tracking axis passing through the pivot points. The tracking axis is non-parallel with the PV plane. The photovoltaic assembly can be rocked along the tracking axis to follow motion of the sun relative to the earth. One or both of the mounting structures can be relatively small, and the off-parallel tracking axis promotes increased efficiency over the course of a year.

### CLAIM OF US PRIORITY

This application claims priority under 35 U.S.C. §119(e)(1) to U.S. Provisional Patent Application Serial No. 61/176,669, filed May 8, 2009, entitled “Photovoltaic Solar Collection and Tracking System”, and bearing Attorney Docket No. S0141/S812.107.101; and the entire teachings of which are incorporated herein by reference.

### STATEMENT REGARDING FEDERALLY SPONSORED RESEARCH OR DEVELOPMENT

This invention was made with Government support under Contract No. DE-FC36-07G017043 awarded by the United States Department of Energy. The Government has certain rights in this invention.

### BACKGROUND

The present disclosure relates to ground mount-type solar energy collectors. More particularly, it relates to photovoltaic systems with solar tracking features.

Solar photovoltaic arrays are used for a variety of purposes, including as a utility interactive power system, a power supply for a remote or un-manned site, a cellular phone switch-site power supply, or a village power supply. These arrays can have a capacity from a few kilowatts to a hundred kilowatts or more, and are typically installed where there is a reasonably flat area with exposure to the sun for significant portions of the day.

In general terms, solar photovoltaic systems (or simply “photovoltaic systems”) employ photovoltaic (PV) cells made of silicon or other materials to convert sunlight into electricity. The cells are packaged in a PV laminate that is generally formed as an array of crystalline or amorphous semiconductor devices electrically interconnected and encapsulated. One or more electrical conductors are carried by the PV laminate through which the solar-generated current is conducted. A single PV laminate can then be assembled to a supportive frame to form a PV module, or can be supported directly (alone or with one or more additional PV laminates) without the use of a frame. As used throughout the specification, the term “PV assembly” (or “photovoltaic assembly”) generically encompasses one or more PV laminates, or one or more PV modules, assembled to a common support structure.

Most large scale PV installations entail mounting an array of PV assemblies to the earth or ground at a location where sunlight is readily present. In order to further improve solar collection efficiency, tracking devices have been employed to keep the PV laminate surfaces in a position close to optimum with respect to the sun for significant portions of the day.

Typical solar tracking systems arrange the laminates in a common plane, with this arrangement being linked to a torque tube or arm that serves as an axis of rotation. For example, FIG. 1 provides a simplified illustration of a conventional photovoltaic solar collection and tracking system 10 including a PV assembly 12 having a plurality of PV laminates 14 (referenced generally) assembled to a frame 16 so as to define a common photovoltaic plane P. Mounting structures 18, 20 pivotably maintain the frame 16 relative to ground, with the frame 16 being pivotable about a tracking axis T established by a torque arm 22 (or similar body), with the tracking axis T being parallel with the photovoltaic plane P. A tracker drive mechanism (not shown) can be used to rotate or rock the frame about the tracking axis T (e.g., the drive mechanism is connected to or actuates the torque arm 22) to keep the PV laminates 14 as square to the sun as possible throughout the day. Usually, the PV laminates 14 are arranged with their axes disposed in a north-south direction, and the tracker gradually rotates the PV laminates 14 throughout the day from an east-facing direction in the morning to a west-facing direction in the afternoon (for Northern Hemisphere installations). The PV laminates 14 are then brought back to the east-facing orientation for the next day. One solar collector arrangement of this type is shown in Barker et al., U.S. Pat. No. 5,228,924. In this arrangement, each row of PV laminates (i.e., individual PV assembly 12) has its own drive mechanism. Other designs, such as that shown in U.S. Pat. No. 6,058,930, employ a single actuator to control multiple rows of PV assemblies 12.

While the above-described solar tracking techniques are well-accepted, tracking the sun requires clearance relative to ground to allow the full tracking motion, necessitating a high rotational axis and therefore high support points (i.e., the mounting structures 18, 20 of FIG. 1. This, in turn, requires larger foundations due to the tracking system being higher up and having higher wind exposure, and also having to resist moment forces. Further, conventional tracking motions do not optimally position the PV laminates 14 at the lower incident angles occurring in the summer months (for Northern Hemisphere installations).

In light of the above, a need exists for improved photovoltaic solar tracking systems.

### SUMMARY

Some aspects in accordance with principles of the present disclosure relate to a photovoltaic solar energy collection and tracking system including a photovoltaic assembly, a first mounting structure, and a second mounting structure. The photovoltaic assembly includes at least one photovoltaic cell maintained by framework in a manner defining a PV plane. The first mounting structure is mountable to a support surface and rotatably maintains the framework at a first pivot point. The second mounting structure is also mountable to the support surface, and rotatably maintains the framework at a second pivot point. In this regard, assembly of the framework to the mounting structures establishes a tracking axis passing through the first and second pivot points, with the tracking axis being non-parallel with the PV plane. With this construction, the photovoltaic assembly can be rocked or rotated about the tracking axis to follow motion of the sun relative to the earth. By forming the tracking axis as being off-parallel with the PV plane, one or both of the mounting structures can be relatively small, and therefore the system entails lower structural costs as compared to conventional designs. Further, the off-parallel tracking axis effectuates a compound angle tracking motion that may promote increased performance or efficiency over the course of a year. In some embodiments, the second mounting structure, and thus the second pivot point, is spatially arranged below a perimeter frame otherwise maintaining the photovoltaic cells. In yet other embodiments, the framework includes a reinforcement assembly forming at least one truss structure, with the second pivot point being established at an apex of the truss.

Other aspects in accordance with principles of the present disclosure relate to a method of collecting energy from the sun. The method includes providing a photovoltaic assembly including at least one photovoltaic cell maintained by framework in a manner defining a PV plane. First and second mounting structures are mounted to a support surface. The framework is pivotably mounted to the first mounting structure at a first pivot point, and to the second mounting structure at a second pivot point. In this regard, a tracking axis is established that passes through the first and second pivot points, with the tracking axis being non-parallel with the PV plane. The photovoltaic assembly is operated to collect energy from sunlight via the photovoltaic cells. Further, the photovoltaic assembly is rotated along the tracking axis to follow a motion of the sun relative to earth. In some embodiments, the support surface is ground or earth, and the mounting structures each include a poured concrete footing formed into the earth.

Yet other aspects in accordance with principles of the present disclosure relate to a solar tracking and photovoltaic support assembly including framework, a first mounting structure and a second mounting structure. The framework is configured for mountably supporting at least one photovoltaic cell in a manner establishing a major PV plane. The mounting structures are mountable to a support surface (e.g., earth or ground). The framework is pivotably assembled to the first mounting structure at a first pivot point, and to the second mounting structure at a second pivot point. A tracking axis is defined as passing through the pivot points, and is non-parallel with the PV plane. With this construction, the framework can be rocked relative to the mounting structures and about the tracking axis to follow motion of the sun relative to earth.

### BRIEF DESCRIPTION OF THE DRAWINGS

FIG. 1 is a simplified, side view of a prior art photovoltaic sun tracking system;

FIG. 2 is a simplified, perspective view of a photovoltaic solar energy collection and tracking system in accordance with principles of the present disclosure, with portions shown in block form;

FIG. 3 is a side view of the system of FIG. 2;

FIG. 4 is an enlarged, perspective view of one example photovoltaic assembly in accordance with principles of the present disclosure and useful with the system of FIG. 2;

FIG. 5A is a side view of the system of FIG. 2 during a solar tracking operation;

FIG. 5B is a top view of the system of FIG. 2 in the orientation of FIG. 5A;

FIG. 6A is a side view of a conventional solar energy collection and tracking system during a solar tracking operation in an orientation corresponding with the orientation of FIG. 5A; and

FIG. 6B is a top view of the system of FIG. 6A.

### DETAILED DESCRIPTION

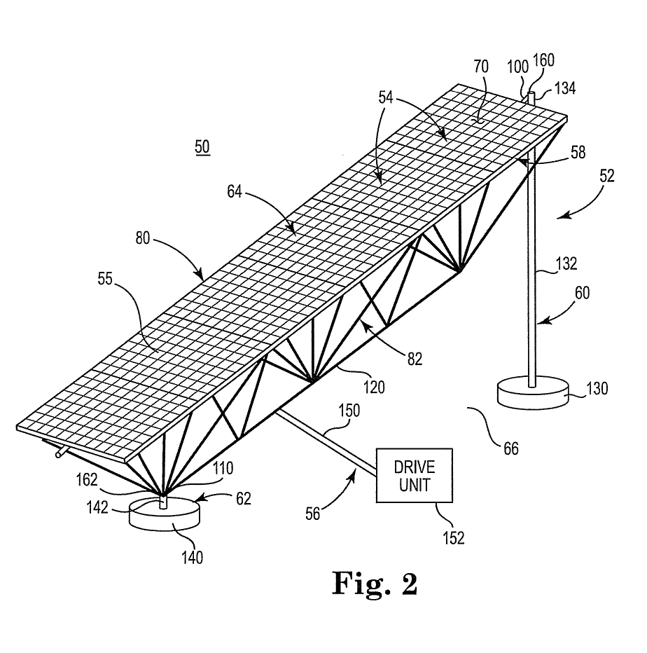

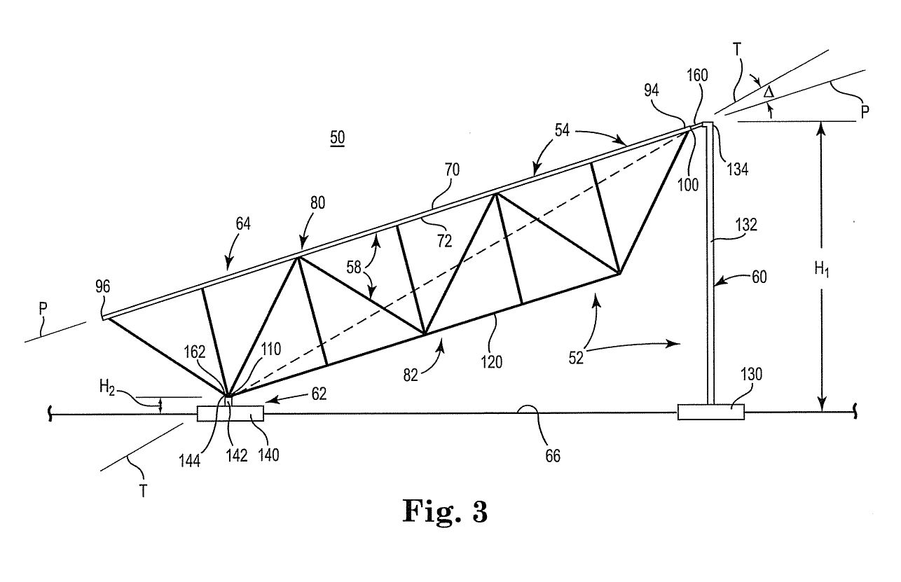

One construction of a photovoltaic (PV) solar energy collection and tracking system 50 in accordance with principles of the present disclosure is shown in FIGS. 2 and 3. The system 50 includes a tracking and support assembly 52 (referenced generally), one or more PV cells 54, and a drive mechanism 56 (omitted from the view of FIG. 3). Details on the various components are provided below. In general terms, however, the tracking and support assembly 52 includes framework 58 and mounting structures 60, 62. The framework 58 combines with the PV cell(s) 54 to define a PV assembly 64, with the system 50 alternatively being described as including the PV assembly 64, the first and second mounting structures 60, 62, and the drive mechanism 56. Regardless, the tracking and support assembly 52 maintains the PV cell(s) 54 in a major PV plane P (identified in FIG. 3) and permits rocking or rotational movement of the PV cell(s) 54 relative to a support surface 66 about a tracking axis T (identified in FIG. 3), with the drive mechanism 56 dictating or controlling the motion. The tracking axis T is non-parallel with the PV plane P, resulting in a compound angle tracking motion.

The PV cell(s) 54 can assume a variety of forms that may or may not be implicated by the Figures. In some constructions, the PV cell(s) 54 are formed as part of a PV laminate 55 that can have any form currently known or in the future developed that is otherwise appropriate for use as a solar photovoltaic device. Further, the system 50 can include a single, large PV laminate 55 or a plurality of PV laminates 5 combining to define a large PV laminate arrangement. In general terms, the PV laminate 55 consists of an array of the photovoltaic cells 54. A glass laminate may be placed over the photovoltaic cells for environmental protection. In some embodiments, the photovoltaic cells 54 advantageously comprise backside-contact cells such as those of the type available from SunPower Corp., of San Jose, Calif. As a point of reference, in backside-contact cells, wirings leading to external electrical circuits are coupled to a backside of the cell (i.e., the side facing away from the sun upon installation) for increased solar collection area. Backside-contact cells are also disclosed in U.S. Pat. Nos. 5,053,083 and 4,927,770, which are both incorporated herein by reference in their entirety. Other types of photovoltaic cells may also be used without detracting from the merits of the present disclosure. For example, the photovoltaic cells 54 can incorporate thin film technology, such as silicon thin films, non-silicon devices (e.g., III-V cells including GaAs, CdTe, CIGs), etc. Further, the PV laminate 55 can be bifacial.

While not shown in the Figures, additional components can be provided with each of the PV laminates 55, such as wiring or electrical components. Further, the PV laminates 55 can be mounted to or maintained by framing components apart from the framework 58. Thus, for example, one or more of the PV laminates 55 can be provided as a standalone PV module (as that term is conventionally employed) and subsequently assembled to the framework 58.

In other constructions contemplated by the present disclosure, the PV cell(s) 54 are provided in a format that may or may not include the PV laminate 55. For example, the systems of the present disclosure can include or relate to PV concentrator devices incorporating optical components such as mirrors and/or lenses (e.g., Fresnel lens) to direct and concentrate sunlight on the PV cell(s) 54.

Regardless of an exact construction, the PV cell 54 defines a PV front surface 70 and a PV rear surface 72 (referenced generally in FIG. 3). As a point of reference, additional components (where provided) associated with the PV cell 54 are conventionally located at or along the PV rear surface 72, and are otherwise omitted from the views. The PV front surface 70 serves as the major solar collecting face of the PV cell 54, and thus is desirably arranged to face the sun during use. Where the system 50 includes two or more of the PV laminates 55 jointly maintained by the framework 58, the PV laminates 55 combine to collectively define the PV front surface 70 and the PV rear surface 72.

With the above understanding of the PV cell(s) 54 in mind, the framework 58 can assume a variety of forms, and generally serves as a support structure or base for the PV cell(s) 54 and corresponding structures (e.g., the PV laminate(s) 55, concentrator components, etc.). In some constructions, the framework 58 includes a perimeter frame 80 and a reinforcement assembly 82. The perimeter frame 80 serves to maintain the PV cell(s) 54 (and related components) in the PV plane P mentioned above, with the reinforcement assembly 82 projecting from the perimeter frame 80 below the PV plane P.

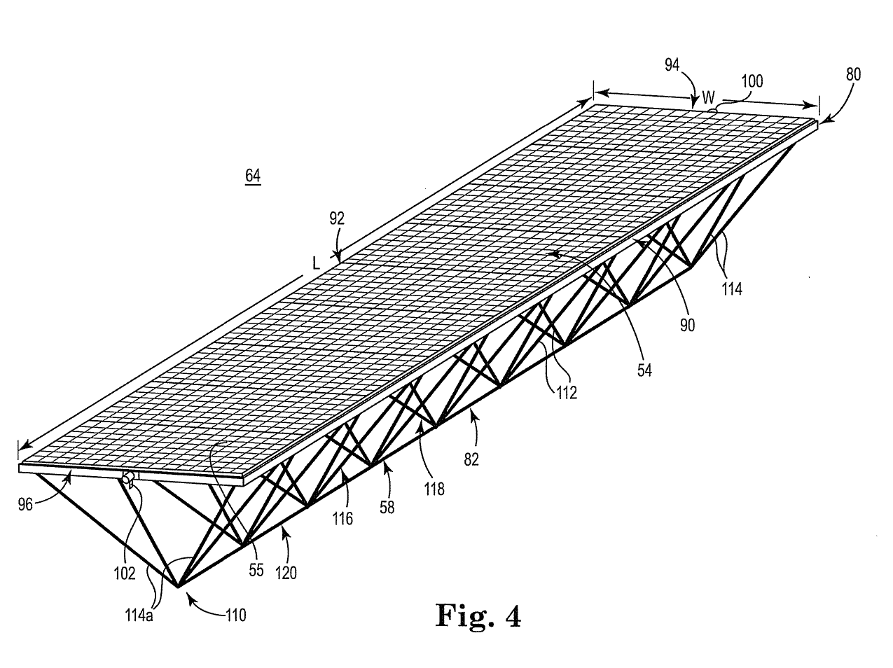

The perimeter frame 80 can form a variety of shapes, and in some configurations is rectangular. For example, and with reference to FIG. 4 that otherwise illustrates the PV assembly 64 apart from other components of the system 50, the perimeter frame 80 can include opposing, first and second side frame members 90, 92 and opposing, first and second end frame members 94, 96. With embodiments in which the perimeter frame 80 is rectangular, the side frame members 90, 92 are identical, and define a length L of the PV assembly 60. Similarly, the end frame members 94, 96 can be identical and define a width W of the PV assembly 64. The length L and width W dimensions, and thus a size/area of the PV laminate(s) 55 (and associated output capacity), where provided, retained by the perimeter frame 80, are relatively large. For example, in some configurations, the length L is not less than 10 feet, alternatively not less than 12 feet, and in other configurations not less than 15 feet. The width W is not less than 5 feet; alternatively, not less than 6 feet. In other constructions, however, the length L and/or the width W can assume lesser dimension and/or the perimeter frame 80 can define a shape other than rectangular. Regardless, the perimeter frame 80 optionally includes one or more coupling posts, such as a first coupling post 100 projecting from the first end frame member 94, and a second coupling post 102 projecting from the second end frame member 96. As described below, the coupling posts 100, 102 facilitate pivotable connection to the first mounting structure 60 (FIG. 2). Alternatively, other pivotable coupling techniques can be employed incorporated with the framework 58, such that the coupling posts 100, 102 can assume other forms and/or can be omitted.

The frame members 90-96 can assume various forms that facilitate mounting of the PV laminates 55 (or other, alternative structures associated with the PV cells 54, such as concentrator components) thereto. For example, the frame members 90-96 can be metal beams or tubes forming a lip- or shelf-type structure adapted to receive and maintain (e.g., via an adhesive) one or more edges of the PV laminates 55. In other constructions, however, the perimeter frame 80 can be formed by a more homogenous or a continuous structure or body that directly contacts or more robustly supports the rear surface 72 (FIG. 3) of the PV laminate(s) 55 (e.g., the frame members 90-96 can be replaced with a single base body to which the PV laminates 55 are mounted). With these and other configurations of the present disclosure, however, where two or more of the PV laminates 55 are included, the PV laminates 55 are maintained by the perimeter frame 80 in a substantially co-planar manner (e.g., respective ones of the PV laminates 54 are within 3° of a true co-planar arrangement relative to one another), with the front surfaces 70 thereof collectively defining the PV plane P mentioned above. For example, where the perimeter frame 80 includes the frame members 90-96, the frame members 90-96 can each form a lip or shelf that is contiguously aligned upon assembly of the frame members 90-96; the lip or shelf is thus substantially planar and serves to establish the PV plane P (FIG. 3) upon assembly of the PV laminates 55 thereto. Further, while the perimeter frame 80 is illustrated as supporting the plurality of the PV laminates 54 in a single row, in other constructions, the PV laminates 55 can be supported by the perimeter frame 80 in two or more rows that may or may not include an identical number of the PV laminates 55. Alternatively, where the PV assembly 64 includes only a single PV laminate 55, the single PV laminate 55 forms the PV plane P. Other constructions of the perimeter frame 80 can alternatively be incorporated to accommodate the various structures relating to the selected format of the PV cells 54, such as where the PV cells 54 are utilized in conjunction with a concentrator device.

The reinforcement assembly 82 can assume a variety of configurations, and in general terms forms or provides a coupling body 110 (referenced generally) that is spaced from the perimeter frame 80 and the PV plane P and is configured for pivotable connection to the second mounting structure 62 (FIG. 2). The coupling body 110 can have various forms or features appropriate for pivotable coupling with a corresponding feature(s) of the second mounting structure 62 (e.g., the coupling body 110 can be a pin sized to be received within a socket provided with the second mounting structure 62).

In some constructions, the reinforcement assembly 82 is adapted to enhance an overall stiffness or strength of the perimeter frame 80, and includes a plurality of rods 112 combining to form one or more truss structures 114 (referenced generally). The rods 112 can be segmented or coupled to one another as first and second rod sets 116, 118. In the assembled configuration of FIG. 4, the rod sets 116, 118 are attached to one another in forming a multiplicity of the stiffness-enhancing truss structures 114. For example, the rods 112 of the first rod set 116 can be assembled to, and project from, the first side frame member 90, whereas the rods 112 of the second rod set 118 can be assembled to, and project from, the second side frame member 92. Regardless, the coupling body 110 is formed at or by an apex of one of the truss structures 114 (identified as the truss structure 114a in FIG. 4). With one acceptable construction of FIG. 4, the reinforcement assembly 82 locates the coupling body 110 spatially below the perimeter frame 80, and thus below the PV plane P. Further, the coupling body 110 is provided spatially between the first and second end frame members 94, 96, but is spatially closer to the second end frame member 96 for reasons made clear below.

In addition to the rod sets 116, 118, in some constructions, the reinforcement assembly 82 further includes a shaft 120 (or two or more shafts or rods linked together along a common axis) extending between and interconnecting the rod sets 116, 118 opposite the perimeter frame 80. As described below, the shaft 120 can function as a torque tube or arm to facilitate driven movement of the PV assembly 64 as part of a solar tracking operation.

The rod sets 116, 118 can assume a variety of forms differing from those reflected in the Figures. In some embodiments, the rod sets 116, 118 are foldable relative to the perimeter frame 80 to provide a compact, shipping format of the PV assembly 64 in which the rod sets 116, 118 are retracted from the orientation shown in the Figures. The rod sets 116, 118 need not be identical, and a greater or lesser number of the rods 112 can be provided. For example, in some constructions, the reinforcement assembly 82 consists of only two or three of the rods 112 that combine to form a single truss structure 114a at which the coupling body 110 is formed or provided. In yet other embodiments, the reinforcement assembly 82 can be constructed or formed by one or more structures that do not include a rod. For example, the reinforcement assembly 82 can be a single, homogenous body projecting from the perimeter frame 80 adjacent the second end frame member 96 and terminating at the coupling body 110.

Returning to FIGS. 2 and 3, the mounting structures 60, 62 can assume various forms appropriate for placement at, and support relative to, the particular support surface 66 associated with an installation site. With some applications, the solar collection and tracking system 50 is configured for placement on the ground (i.e., the earth), with the mounting structures 60, 62 configured for affixment into the earth (or equivalent foundation). In general terms, then, the mounting structures 60, 62 can each include at least one footing and at least pier. For example, the first mounting structure 60 includes a footing 130 and a pier 132. The footing 130 can be a poured concrete footing (e.g., poured in the ground or earth 66), for example 3,000 psi concrete, about 2 feet in diameter and about 5-6 feet in depth, with the soil about it being re-compacted. An additional foundation (not shown) can also be formed in the ground or earth 66 within which the footing 130 is supported. The pier 132 is rigidly supported by, and extends from, the footing 130, terminating at a leading end 134 to define a first mounting structure height H₁ (identified in FIG. 3). The leading end 134, in turn, is configured for pivoting connection to the framework 58, for example, via a rotatable journal bearing-type assembly with the first coupling post 100. While the first mounting structure 60 is illustrated as including a single footing 130/pier 132, in other constructions, one or more additional footing 130/pier 132 arrangements can be provided as part of the first mounting structure 60 that collectively establish the pivoting relationship and support of the framework 58.

The second mounting structure 62 also includes a footing 140 and a pier 142. Once again, the footing 140 can be a poured concrete footing, with the pier 142 rigidly maintained by, and extending from, the footing 140 and terminating at a leading end 144. A second mounting structure height H₂ (identified in FIG. 3) established by the pier 142 is less than, and in some constructions significantly less than (e.g., 25% or less), the height H₁ of the first mounting structure 60 for reasons made clear below. Further, the leading end 144 is configured for pivoting assembly with the coupling body 110 can of the framework 58 (i.e., the leading end 144 and the coupling body 110 incorporate complimentary features that establish a pivotable or rotatable relationship upon final assembly).

With specific reference to FIG. 2, the drive mechanism 56 can have a variety of constructions appropriate for effectuating rocking motion of the PV assembly 64 relative to the mounting structure 60, 62. In general terms, the drive mechanism 56 includes one or more links 150 (illustrated schematically) that can be connected to the framework 58 (e.g., the shaft or torque tube 120), as well as a motorized drive unit 152 (e.g., motorized linear actuator) capable of driving the link 150 in a reciprocating manner. Some examples of acceptable drive mechanisms are described in U.S. Pat. No. 6,058,930, the teachings of which are incorporated herein by reference.

Construction of the solar energy collection and tracking system 50 to the support surface 66 includes constructing/mounting the mounting structures 60, 62 to or on the support surface 66 as described above, with the mounting structures 60, 62 being spaced from one another. The PV assembly 64 is then connected to the mounting structure 60, 62. With specific reference to FIG. 3, the first coupling post 100 is pivotably or rotatably assembled to the pier 132 of the first mounting structure 60, for example at the leading end 134. A variety of techniques and/or designs can be employed to effectuate the rotatable coupling; regardless, a first pivot point 160 is established at which the framework 58 pivots relative to the first mounting structure 60. The framework 58 is similarly rotatably or pivotably coupled to the second mounting structure 62, for example via an interface between the coupling body 110 and the leading end 144 of the pier 142 associated with the second mounting structure 62. Once again, a variety of techniques and/or designs can be employed to effectuate the pivotable relationship. A second pivot point 162 is established at which the framework 58 pivots relative to the second mounting structure 62. Finally, the drive mechanism 56 (FIG. 2) is installed and mechanically linked to the PV assembly 64 (e.g., via the torque shaft 120).

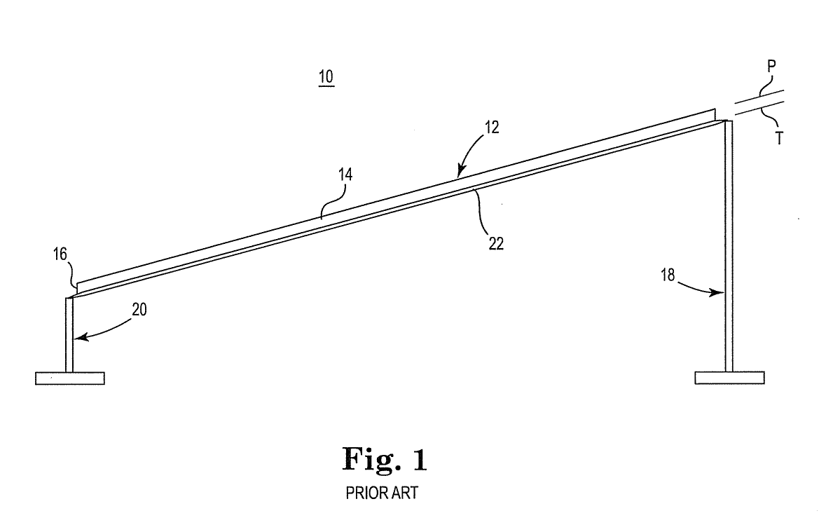

The above construction defines the tracking axis T as extending through the first and second pivot points 160, 162. As shown, and in contrast to conventional solar tracking designs, the tracking axis T is non-parallel relative to the PV plane P. For example, the tracking axis T and the PV plane P combine to define an included angle Δ in the range of 3°-70°; in some embodiments in the range of 5°-60°. Further, while the arrangement of FIG. 3 reflects the PV plane P (and thus the PV laminates 54 (referenced generally)) as being tilted relative to the support surface 66, in other constructions, the PV plane P can be substantially planar relative to the support surface 66. The first pivot point 160 is formed or located immediately adjacent the first end 94 of the perimeter frame 50, whereas the second pivot point 162 is located spatially below the PV plane P, and spatially between the opposing ends 94, 96 of the perimeter frame 80. As a result, the second mounting structure 62 can be significantly smaller (i.e., the height H₂ of the second mounting structure 62 is significantly less than the height H₁ of the first mounting structure 60), thereby reducing the fabrication and material costs associated with at least the second mounting structure 62 as compared to conventional tracking systems (e.g., the second mounting structure 20 of FIG. 1).

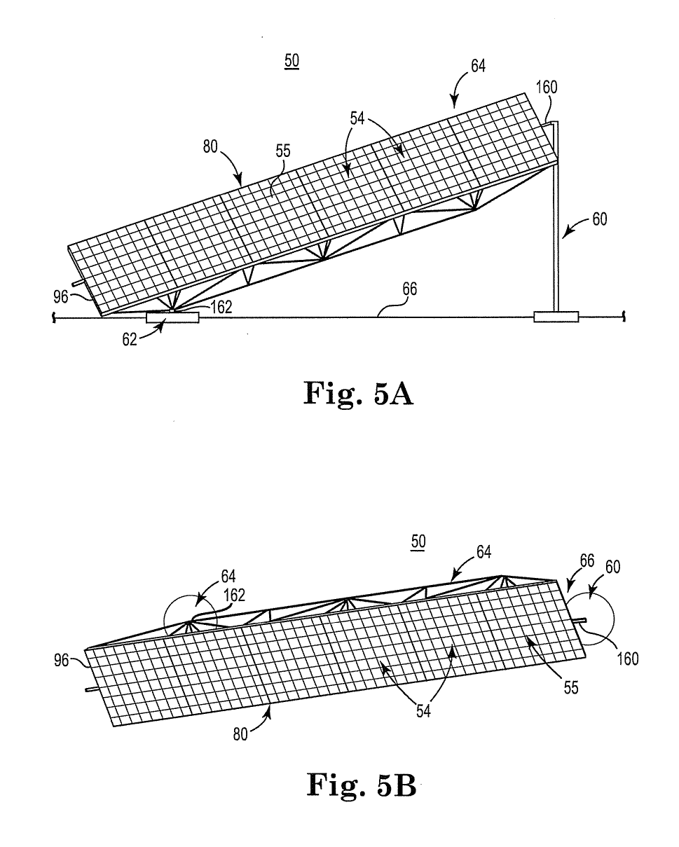

Following installation, the system 50 operates to collect and convert sunlight into electrical energy in manners conventionally found with photovoltaic applications. Further, the PV assembly 64 is maneuvered (e.g., rocked) to track the position of the sun relative to the support surface 66. As a point of reference, with the installations implicated by FIG. 3, the PV assembly 64 is arranged so as to tilt or face the PV plane P towards the south in Northern Hemisphere installations (or to the north in Southern Hemisphere installations). Tracking thus consists of the PV assembly 64 rocking or rotating about the tracking axis T from an east-looking orientation in the morning to a west-looking orientation in the evening. The east-looking orientation is shown in FIGS. 5A and 5B (with the drive mechanism 56 (FIG. 2) being omitted for ease of illustration). In the east-looking orientation, the PV laminate(s) 55 (alternatively, the concentrator components) is arranged at a lower incident angle (as compared to a conventional tracking arrangement in which the tracking axis is parallel with the PV plane). In the summer months (for Northern Hemisphere installations), this lower incident angle more accurately coincides with a position of the sun relative to the support surface 66, thereby enhancing an overall efficiency of the system 50.

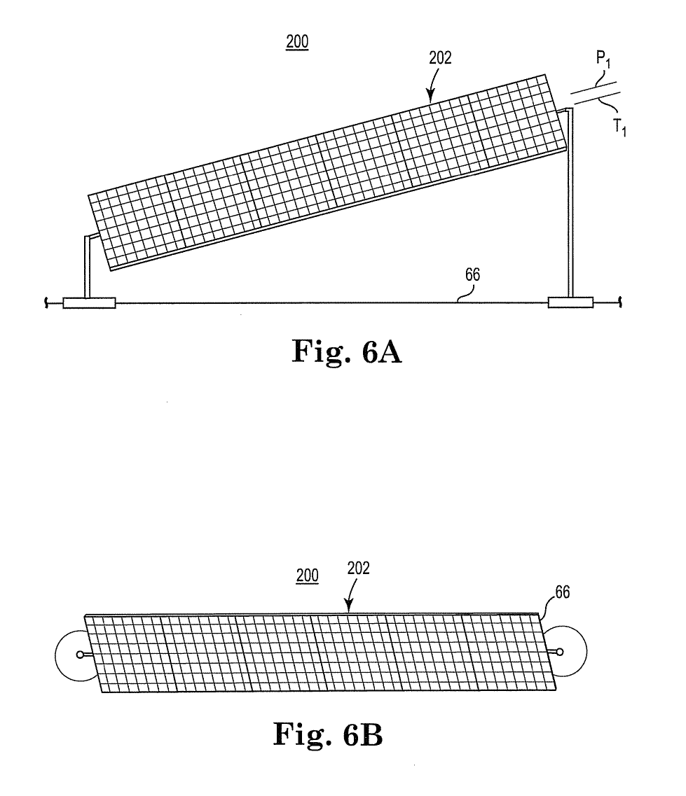

Further, because the second pivot point 162 is located in highly close proximity to the support surface 66 (at the east-looking orientation), the perimeter frame 80 (e.g., the second end frame member 96) is located closer to the support surface 66 (as compared to a conventional tracking arrangement), thereby presenting a lower wind profile to the PV assembly 64. By way of comparison, FIGS. 6A and 6B illustrate the east-facing orientation of a solar energy collection and tracking system 200 incorporating a conventional arrangement in which the tracking axis T₁ and the PV plane P₁ (referenced generally relative to the orientation of FIG. 6A) are parallel. As evidenced by a comparison of FIGS. 6A and 6B with FIGS. 5A and 5B, perimeter frame 202 of the conventional system 200 is spaced further from the support surface 66 (in at least the east-facing orientation) as compared to the perimeter frame 80/support surface 66 spacing with the system 50 of the present disclosure, resulting in the lower wind profile mentioned above. The lower wind profile, in turn, dictates that at least the second mounting structure 62 can have a lesser structural configuration (as compared to the conventional arrangement) thereby reducing overall costs.

The solar energy collection and tracking systems of the present disclosure provide a marked improvement over previous designs. By establishing a tracking axis that is off of parallel relative to the PV plane, the corresponding foundation or mounting structure(s) can be reduced. Further, the tracking motion created by a positive angle rotation axis and a relative negative angle PV plane can increase the efficiency or performance over the course of a year.

Although the present disclosure has been described with reference to preferred embodiments, workers skilled in the art will recognize that changes can be made in form and detail without departing from the spirit and scope of the present disclosure.

What is claimed is:

1. A photovoltaic solar energy collection and tracking system comprising:
a photovoltaic assembly including:
at least one photovoltaic cell, framework maintaining the photovoltaic cell in a manner defining a PV plane;
a first mounting structure mountable to a support surface and rotatably maintaining the framework at a first pivot point; and
a second mounting structure mountable to the support surface and rotatably maintaining the framework at a second pivot point;
wherein assembly of the framework to the mounting structures establishes a tracking axis passing through the first and second pivot points, the tracking axis being non-parallel with the PV plane;
and further wherein the photovoltaic assembly can be rocked about the tracking axis to follow motion of the sun relative to earth.

2. The system of claim 1, further comprising:
a drive mechanism linked to the framework and operable to effectuate movement of the photovoltaic assembly.

3. The system of claim 1, wherein the framework includes:
a perimeter frame maintaining a PV laminate; and
a reinforcement assembly projecting from the perimeter frame in a direction below the PV plane.

4. The system of claim 3, wherein the first pivot point is established at the perimeter frame and the second pivot point is established at the reinforcement assembly.

5. The system of claim 4, wherein the first pivot point is formed along the PV plane and the second pivot point is formed below the PV plane.

6. The system of claim 3, wherein the reinforcement assembly includes a plurality of rods forming at least one truss structure, the second pivot point being established at an apex of the truss structure.

7. The system of claim 3, wherein the perimeter frame is rectangular, having opposing, first and second ends defining a length and opposing sides defining a width, and further wherein the first pivot point is established immediately adjacent the first end and the second pivot point is spatially established between the first and second ends.

8. The system of claim 7, wherein the second pivot point is spatially below the first pivot point.

9. The system of claim 7, wherein a linear distance between the first and second pivot points is less than the length of the perimeter frame.

10. The system of claim 1, wherein the photovoltaic assembly includes a plurality of photovoltaic laminates maintained by the framework at the PV plane.

11. The system of claim 1, wherein the tracking axis and the PV plane form an included angle in the range of 5°-60°.

12. The system of claim 1, wherein the first and second mounting structures each include:
a pier and a footing supported in a foundation.

13. The system of claim 12, wherein the footing is poured concrete.

14. A method of collecting energy from the sun, the method comprising:
providing a photovoltaic assembly including:
at least one photovoltaic cell, framework maintaining the photovoltaic cell in a manner to defining a PV plane;
mounting a first mounting structure to a support surface;
mounting a second mounting structure to the support surface at a location spaced from the first mounting structure;
pivotably mounting the framework to the first mounting structure at a first pivot point and to the second mounting structure at a second pivot point;
wherein a tracking axis passing through the first and second pivot points is established, the tracking axis being non-parallel with the PV plane;
operating the PV cell to collect energy from sunlight; and
rocking the photovoltaic assembly along the tracking axis to follow a motion of the sun relative to earth.

15. The method of claim 14, wherein the support surface is the earth, and mounting the first and second mounting structures includes pouring a concrete footing into the earth.

16. The method of claim 15, wherein the second support structure is spatially beneath the framework.

17. The method of claim 14, wherein the framework includes a rectangular perimeter frame maintaining the photovoltaic laminate and having opposing ends and opposing sides, and further wherein pivotably mounting the framework to the first and second mounting structures includes locating the first end spatially above the second end.

18. The method of claim 14, wherein the tracking axis and the PV plane form an included angle in the range of 5°-60°.

19. The method of claim 14, wherein the framework includes a torque shaft defining a torque arm axis that is non-parallel with the tracking axis, the method further including:
linking a drive mechanism to the torque arm;
wherein rocking the photovoltaic assembly includes operating the drive mechanism to apply a force to the torque arm.

20. A solar tracking and photovoltaic support assembly comprising:
framework configured for mountably supporting at least one photovoltaic cell in a manner establishing a PV plane;
a first mounting structure configured to be mounted to a support surface;
a second mounting structure configured to be mounted to the support surface;
wherein the framework is pivotably assembled to the first mounting structure at a first pivot point and to the second mounting structure at a second pivot point to define a tracking axis passing through the first and second pivot points, the tracking axis being non-parallel with the PV plane;
and further wherein the framework can be rocked relative to the mounting structures about the tracking axis to follow a motion of the sun relative to earth.
